(19) United States
(12) Patent Application Publication
(10) Pub. No.: US 2024/0151750 A1
(43) Pub. Date: May 9, 2024

(54) SERVER AND VEHICLE COMMUNICATING THEREWITH

(71) Applicants: HYUNDAI MOTOR COMPANY, Seoul (KR); KIA CORPORATION, Seoul (KR)

(72) Inventor: Wonseok JIN, Suwon-si (KR)

(73) Assignees: Hyundai Motor Company, Seoul (KR); KIA CORPORATION, Seoul (KR)

(21) Appl. No.: 18/232,062

(22) Filed: Aug. 9, 2023

(30) Foreign Application Priority Data
Nov. 3, 2022 (KR) 10-2022-0145357

(51) Int. Cl. G01R 19/165; G07C 5/00; G07C 5/08; H01M 10/42; H01M 10/46; H04L 67/12

(52) U.S. Cl. CPC G01R 19/16542; G07C 5/008; G07C 5/085; H01M 10/425; H01M 10/46; H04L 67/12; B60L 58/22

(57) ABSTRACT

A server learns inference information for inferring a voltage difference value between a first battery and a second battery, and a vehicle communicates with the server. The vehicle includes: a low-voltage DC-DC converter (LDC); a first battery; a second battery; a battery equalizer (BEQ); a memory; and a processor configured to obtain output difference value between an output value of the LDC and an output value of the BEQ, obtain the voltage difference value corresponding to the obtained output difference value based on the inference information, and determine a charge time of the first battery and the second battery based on the obtained voltage difference value and a reference value.

### CROSS-REFERENCE TO RELATED APPLICATION

The present application claims priority to Korean Patent Application No. 10-2022-0145357, filed on Nov. 3, 2022, the entire contents of which is incorporated herein for all purposes by this reference.

### BACKGROUND OF THE PRESENT DISCLOSURE

### Field of the Present Disclosure

The present disclosure relates to a server for improving voltage unbalancing of a plurality of batteries and a vehicle communicating therewith.

### Description of Related Art

Vehicles may be divided into internal combustion engine vehicles and eco-friendly vehicles based on a power source.

The eco-friendly vehicle may be classified into an electric vehicle and a hybrid vehicle. An electric vehicle includes a drive motor and a battery which is rechargeable power, rotates the drive motor with electricity accumulated in the battery and drives wheels using the rotation of the drive motor. A hybrid vehicle includes an engine, a battery and a drive motor and drives by controlling a mechanical power of the engine and an electric power of the drive motor.

An eco-friendly vehicle includes a high-voltage battery (also referred to as a main battery) storing electrical energy provided to an electric motor supplying rotation force to wheels, and a low-voltage battery (also referred to as an auxiliary battery) supplying electric power to electronic/electric loads of the vehicle such as headlights, wipers, and the like.

An eco-friendly vehicle includes a low-voltage DC-DC converter (LDC). The LDC performs low voltage direct current conversion between the main battery and the auxiliary battery to secure startability of vehicle using the auxiliary battery and durability of the auxiliary battery. Also, the LDC steps down a voltage of the main battery and applies to the auxiliary battery to charge the auxiliary battery. Here, charging the auxiliary battery is referred to as a supplementary charging.

Conventionally, supplementary charging of an auxiliary battery is periodically performed each time a predetermined time period has elapsed, or the auxiliary battery is automatically supplementarily charged when a state of charge (SOC) value of an auxiliary battery drops below a certain SoC due to excessive use of power of the auxiliary battery by a driver.

The above-described methods of charging an auxiliary battery are performed by reflecting an SOC value of the auxiliary battery. Accordingly, when a capacity of the auxiliary battery itself is reduced due to aging, even though the auxiliary battery is charged to a reference SOC value, sufficient charge current amount may not be secured.

Conventional supplementary charging control technologies for auxiliary battery have been limited to supplementary charging of an auxiliary battery provided in a passenger vehicle. That is, the conventional supplementary charging control technologies for auxiliary battery are not applicable to supplementary charging control for commercial vehicles using two auxiliary batteries.

Accordingly, voltage unbalancing occurs in first and second auxiliary batteries of a commercial vehicle. That is, as a usage time of the commercial vehicle increases, aging of the second auxiliary battery is relatively severe compared to the first auxiliary battery, increasing a voltage difference between the first and second auxiliary batteries. As a result, a low voltage error may occur in the first and second auxiliary batteries, causing the commercial vehicle not to start.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a server which may learn a difference value between a voltage value of a first battery detected by a first voltage sensor and a voltage value of a second battery detected by a second voltage sensor, and a difference value between an output of a low-voltage DC-DC converter (LDC) and an output of a battery equalizer (BEQ), inferring a voltage difference value between the first and second batteries and transmitting information related to the inferred voltage difference value of the first and second batteries to a vehicle.

Another aspect of the present disclosure provides a vehicle which may learn a difference value between an output of a LDC and an output of a BEQ, infer a voltage difference value between first and second batteries based on the learned information, and control charging of the first and second batteries based on a reference value and the inferred voltage difference value between the first and second batteries.

Additional aspects of the present disclosure will be set forth in part in the description which follows, and in part, will be obvious from the description, or may be learned by practice of the present disclosure.

According to an aspect of the present disclosure, there is provided a server including: a communicator configured to perform communication with a first voltage sensor configured to detect a voltage value of a first battery, a second voltage sensor configured to detect a voltage value of a second battery, a low-power converter, and a battery equalizer (BEQ); and a processor configured to: obtain a voltage difference value between the voltage value of the first battery detected by the first voltage sensor and the voltage value of the second battery detected by the second voltage sensor, obtain output difference value between an output value of the low-power converter and an output value of the BEQ, and transmit, to a vehicle, a voltage difference value corresponding to the output difference value as inference information.

The processor of the server according to an aspect of the present disclosure is configured to obtain a plurality of voltage difference values for a predetermined time period, divide a plurality of output difference value obtained for a predetermined time period into a plurality of sections, perform learning to obtain a representative value of voltage difference values for each of the divided sections, and obtain, as the inference information, the representative value of the voltage difference values for each of the divided sections obtained as a result of the learning.

The processor of the server according to an aspect of the present disclosure is configured to generate a histogram of the voltage difference values for each of the divided sections, determine whether the generated histogram has normality, set an average value of the voltage difference values as the representative value when the processor concludes that the generated histogram has the normality, and set a median value of the voltage difference values as the representative value when the processor concludes that the generated histogram has no normality, set a median value of the voltage difference values as the representative value.

The processor of the server according to an aspect of the present disclosure is configured to determine that a performance is satisfied and complete the learning, based on an accuracy between the set representative value and the obtained voltage difference value being greater than or equal to a first reference accuracy.

The processor of the server according to an aspect of the present disclosure is configured to perform learning to obtain an output representative value of a plurality of output difference values obtained for a predetermined time period, perform learning to obtain a voltage representative value of a plurality of voltage difference values obtained for the predetermined time period, and obtain, as the inference information, the output representative value and the voltage representative value.

The processor of the server according to an aspect of the present disclosure is configured to learn a first pattern of a plurality of output difference values obtained for a predetermined time period and a second pattern of a plurality of voltage difference values obtained for the predetermined time period, and obtain, the inference information based on the learned first pattern and second pattern.

The processor of the server according to an aspect of the present disclosure is configured to generate windows of the plurality of output difference values obtained for the predetermined time period, divide the generated windows into a train set, a validation set, and a test set, generate a model using the train set, validate the generated model using the validation set, select output difference value that maximizes a performance of the validation set, evaluate a performance of the selected output difference value using the test set, and based on the performance being satisfied, complete the learning.

The processor of the server according to an aspect of the present disclosure is configured to determine an accuracy and a F1 score based on the selected output difference value and the obtained time-series data, and based on the determined accuracy being greater than or equal to a second reference accuracy and the determined F1 score being greater than or equal to a reference score, determine that the performance is satisfied.

The processor of the server according to an aspect of the present disclosure is configured to generate windows of the voltage difference values obtained for the predetermined time period, divide the generated windows into a train set, a validation set, and a test set, generate a model using the train set, validate the generated model using the validation set, select a voltage difference value that maximizes a performance of the validation set, evaluate a performance of the selected voltage difference value using the test set, and based on the performance being satisfied, complete the learning.

The processor of the server according to an aspect of the present disclosure is configured to determine an accuracy and a F1 score based on the selected voltage difference value and the obtained voltage difference value, and based on the determined accuracy being greater than or equal to a third reference accuracy and the determined F1 score being greater than or equal to a reference score, determine that the performance is satisfied.

The processor of the server according to an aspect of the present disclosure is configured to use a recurrent neural network (RNN) model or a convolutional recurrent neural network (CRNN) model for the learning.

According to another aspect of the present disclosure, there is provided a vehicle including: an LDC configured to convert a voltage of a high-voltage battery into a first voltage; a first battery connected to the LDC; a second battery connected to the first battery; a BEQ connected to the LDC, the first battery, the second battery and a load, and configured to convert the first voltage applied to the BEQ into a second voltage, and maintain a voltage balance between the first battery and the second battery using the second voltage; a memory configured to store inference information related to a voltage difference value corresponding to output difference value received from a server; and a processor configured to obtain output difference value between an output value of the LDC and an output value of the BEQ, obtain a voltage difference value corresponding to the obtained output difference value based on the inference information stored in the memory, and determine a charge time of the first battery and the second battery based on the obtained voltage difference value and a reference value.

The processor of the vehicle according to another aspect of the present disclosure is configured to determine whether the obtained voltage difference value exceeds the reference value, identify a rate where the obtained voltage difference value exceeds the reference value based on a determination that the obtained voltage difference value exceeds the reference value, and determine as the charge time of the first battery and the second battery based on a determination that the identified rate is greater than or equal to a reference rate.

The processor of the vehicle according to another aspect of the present disclosure is configured to determine whether it is the charge time of the first battery and the second battery, in response to a number of driving cycles reaching a preset number of times.

The processor of the vehicle according to another aspect of the present disclosure is configured to obtain a plurality of output difference values for a predetermined time period, and perform learning to obtain a representative value of a plurality of pieces of the plurality of output difference values.

The processor of the vehicle according to another aspect of the present disclosure is configured to divide the plurality of output difference values obtained for the predetermined time period into a plurality of sections, generate a histogram of the plurality of output difference values for each of the divided sections, determine whether the generated histogram has normality, set an average value of the plurality of output difference values as the representative value when the processor concludes that the generated histogram has the normality, and set a median value of the plurality of output difference values as the representative value when the processor concludes that the generated histogram has no normality.

The processor of the vehicle according to another aspect of the present disclosure is configured to determine that a performance is satisfied and complete the learning, based on an accuracy between the set representative value and the obtained output difference value being greater than or equal to a first reference accuracy.

The processor of the vehicle according to another aspect of the present disclosure is configured to generate windows of the plurality of pieces of output difference value obtained for the predetermined time period, divide the generated windows into a train set, a validation set, and a test set, generate a model using the train set, validate the generated model using the validation set, select output difference value that maximizes a performance of the validation set, evaluate a performance of the selected output difference value using the test set, and based on the performance being satisfied, complete the learning.

The processor of the vehicle according to another aspect of the present disclosure is configured to determine an accuracy and a F1 score based on the selected output difference value and the obtained time-series data, and determine that the performance is satisfied based on the determined accuracy being greater than or equal to a third reference accuracy and the determined F1 score being greater than or equal to a reference score.

The processor of the vehicle according to another aspect of the present disclosure is configured to use a RNN model or a CRNN model for the learning.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram illustrating a configuration of a power system of a vehicle according to an exemplary embodiment of the present disclosure;

FIG. 2 is a control block diagram illustrating a configuration of a server according to an exemplary embodiment of the present disclosure;

FIG. 3 is a graph of an output current of a low voltage DC-DC converter (LDC) received in a server according to an exemplary embodiment of the present disclosure;

FIG. 4 is a graph of voltages of a first battery and a second battery detected by a first voltage sensor and a second voltage sensor, respectively, both of which perform communication with a server according to an exemplary embodiment of the present disclosure;

FIG. 5 illustrates an example of a histogram generated in a server according to an exemplary embodiment of the present disclosure;

FIG. 6 illustrates an example of time-series data of output difference values of a server according to an exemplary embodiment of the present disclosure;

FIG. 7 and FIG. 8 illustrate examples of windows generated in a server according to an exemplary embodiment of the present disclosure;

FIG. 9 is a diagram illustrating an example of a learning model of a server according to an exemplary embodiment of the present disclosure;

FIG. 10 is a flowchart illustrating operations of representative value learning in learning of a server according to an exemplary embodiment of the present disclosure;

FIG. 11 is a flowchart illustrating operations of pattern learning in learning of a server according to an exemplary embodiment of the present disclosure; and

FIG. 12 is a flowchart illustrating a control of a vehicle according to an exemplary embodiment of the present disclosure.

It may be understood that the appended drawings are not necessarily to scale, presenting a somewhat simplified representation of various features illustrative of the basic principles of the present disclosure. The predetermined design features of the present disclosure as included herein, including, for example, specific dimensions, orientations, locations, and shapes will be determined in part by the particularly intended application and use environment.

In the figures, reference numbers refer to the same or equivalent portions of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Like reference numerals throughout the specification denote like elements. Also, the present specification does not describe all the elements according to various exemplary embodiments of the present disclosure, and descriptions well-known in the art to which the present disclosure pertains or overlapped portions are omitted. The terms such as “—part”, “—module”, and the like may refer to at least one process processed by at least one hardware or software. According to various exemplary embodiments of the present disclosure, a plurality of “parts”, “—modules” may be embodied as a single element, or a single of a “part”, “—module” may include a plurality of elements.

It will be understood that when an element is referred to as being “connected” to another element, it may be directly or indirectly connected to the other element, wherein the indirect connection includes “connection” via a wireless communication network.

It will be understood that the term “include” when used in the present specification, specifies the presence of stated features, integers, steps, operations, elements, and/or components, but does not preclude the presence or addition of at least one other features, integers, steps, operations, elements, components, and/or groups thereof.

It will be understood that when it is stated in the present specification that a member is located “on” another member, not only a member may be in contact with another member, but also yet another member may be present between the two members.

It will be understood that, although the terms first, second, etc. may be used herein to describe various elements, these elements should not be limited by these terms.

It is to be understood that the singular forms are intended to include the plural forms as well, unless the context clearly dictates otherwise.

Reference numerals used for method steps are just used for convenience of explanation, but not to limit an order of the steps. Thus, unless the context clearly dictates otherwise, the written order may be practiced otherwise.

Hereinafter, an operation principle and embodiments will be described in detail with reference to the accompanying drawings.

Vehicles may be divided into a passenger vehicle used for personal use and movement, and a commercial vehicle used for commercial use and transporting people or cargo.

The commercial vehicle may include trucks, dump trucks, vans, forklifts, and specialty vehicles as well as buses and taxis that transport people.

A vehicle according to the exemplary embodiment of the present disclosure may be an eco-friendly vehicle driven by electricity to reduce fuel consumption and emission of harmful gases.

In the exemplary embodiment of the present disclosure, a commercial vehicle including two low-voltage batteries is referred to as an example.

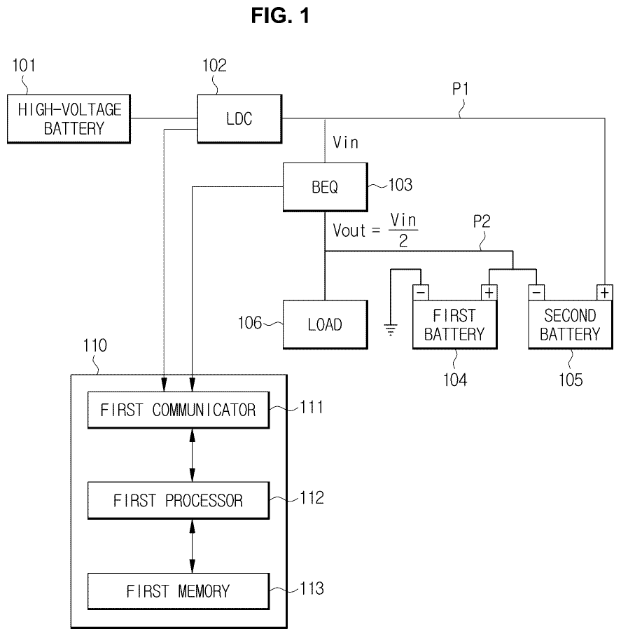

FIG. 1 is a block diagram illustrating a configuration of a power system of a vehicle according to an exemplary embodiment of the present disclosure.

A vehicle includes a high-voltage battery 101, a low-voltage DC-DC converter (LDC, 102), a battery equalizer (BEQ, 103), a first battery 104, a second battery 105, a load 106, and a charging controller 110.

The high-voltage battery 101 supplies power to a drive motor connected to wheels of the vehicle.

The high-voltage battery 101 supplies power for charging the first battery 104 and the second battery 105.

The high-voltage battery 101 may perform charging thereof by receiving power from an external power source. That is, the high-voltage battery 101 may be a rechargeable battery.

The high-voltage battery 101 is also referred to as a main battery.

Here, a high-voltage may be a voltage greater than a preset voltage.

The LDC 102 may convert a voltage of the high-voltage battery 101 into a voltage of a predetermined magnitude, and apply the converted voltage to at least one of the first battery 104, the second battery 105, or the load 106.

That is, the LDC 102 may be configured to supply power to the load 106 and charge the first battery 104 and the second battery 105.

The LDC 102 may convert the voltage of the high-voltage battery 101 into a direct current voltage of approximately 24V.

The LDC 102 may output the voltage of approximately 24V to the first battery 104 and the BEQ 103 through a power line P1.

For example, the LDC 102 may include at least one switching circuit and inductor (coil, etc.).

As an exemplary embodiment of the present disclosure, the LDC 102 may include at least one of a coil that blocks current of frequency higher than a certain level and only passes direct current or current of frequency lower than a certain level, a transformer that increases or drops voltage, a smoothing circuit (iron core coil or condenser) that removes ripple on an output side of DC power, or a switching circuit.

For example, the smoothing circuit may include an iron core coil or a condenser, and the switching circuit may include a metal-oxide-semiconductor field-effect transistor (MOSFET).

The above constituent components are only an example of the LDC, and the LDC is not limited thereto.

The BEQ 103 may be connected to the LDC 102 and a point where the first battery 104 and the second battery 105 are connected. Also, the BEQ 103 may be connected to the load 106.

The BEQ 103 may be connected in parallel to the LDC 102 and the point between the first battery 104 and the second battery 105.

The BEQ 103 may convert an input voltage (Vin) of 24V into an output voltage (Vout) which is a half of the input voltage. That is, the BEQ 103 may output a DC voltage of approximately 12V. The BEQ 103 may be a power converter.

The BEQ 103 may be connected to the LDC, and convert a first voltage converted by the LDC and applied to the BEQ 103 into a second voltage.

The BEQ 103 may output a voltage of approximately 12V to the load 106 and the point between the two batteries through a power line P2.

The output of the BEQ 103 may be connected to a positive terminal of the second battery 105 and the power-converted output may be supplied to the second battery 105.

The BEQ 103 may prevent the first battery 104 from being charged and the second battery 105 from being discharged, when supplying power to the first battery and the second battery from the LDC 102. Accordingly, voltages of the first battery 104 and the second battery 105 may be balanced. Thus, the BEQ 103 may minimize a damage to the first battery 104 and the second battery 105 and extend lifespans of the first battery 104 and the second battery 105.

The BEQ 103 may apply the power-converted output to the load 106, allowing the load 106 to be operated.

The first battery 104 may be a battery configured for being charged or discharged, and be a low-voltage battery. A low voltage may be less than or equal to a predetermined voltage. For example, the low voltage may be approximately 12V.

A positive terminal of the first battery 104 may be connected to the LDC 102 and the BEQ 103.

The second battery 105 may be a battery configured for being charged or discharged, and be a low-voltage battery. A voltage of the second battery 105 may be the same as that of the first battery 104.

A positive terminal of the second battery 105 may be connected to a negative terminal of the first battery 104. The negative terminal of the second battery 105 may be grounded. That is, the second battery 105 may be connected in series to the first battery 104 in terms of a relationship with the first battery 104.

A contact point between the positive terminal of the second battery 105 and the negative terminal of the first battery 104 may be connected to the load 106 and the BEQ 103.

That is, the second battery 105 may be connected in parallel to the first battery 104 in terms of a relationship between the first battery 104 and the BEQ 103.

The first battery 104 and the second battery 105 connected in series may supply power to the load 106, allowing the load 106 to be operated.

The first battery 104 and the second battery 105 may supply power to the load 106 while the vehicle is parked.

The first battery 104 and the second battery 105 may be an auxiliary battery of the vehicle.

The load 106 may be connected to the BEQ 103, and connected to the first battery 104 and the second battery 105 connected in series.

The load 106 may be operated using the power applied from the BEQ 103.

The load 106 may be operated using the power applied from the first battery 104 and the second battery 105 connected in series.

The load 106 may be an electronic device operated using a low voltage.

The low-voltage electronic device may receive a voltage less than or equal to a preset voltage and operate using the applied voltage.

Here, the low voltage may be approximately 12V.

The load 106 may be operated regardless of turning ON/OFF the vehicle.

The load 106 may include basic electronic devices necessarily required for the vehicle, such as headlights or wipers, or include electronic devices for entertainment, convenience and safety.

The charging controller 110 may include a first communicator 111, a first processor 112 and a first memory 113.

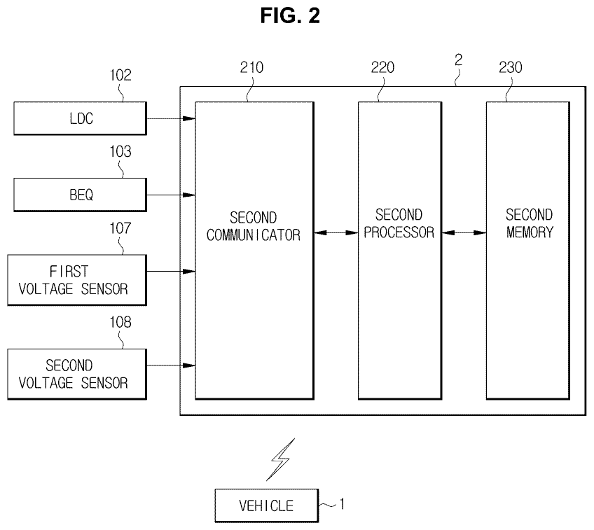

To differentiate constituent components of the charging controller 110 from those of a server 2, among the constituent components having the same name, the constituent components of the charging controller 110 are referred to as “first” component, and the constituent components of the server 2 (refer to FIG. 2) are referred to as “second” component.

The first communicator 111 may include at least one constituent component enabling communication with the server 2, communication among the constituent components of the charging controller 110, and communication among constituent components of the vehicle. For example, the first communicator 111 may include at least one of a short-range communication module, wireless communication module, or a wired communication module.

The short-range communication module may include a variety of short-range communication modules that transmit and receive signals in a short distance using a wireless communication network, such as a Bluetooth module, infrared communication module, radio frequency identification (RFID) communication module, wireless local access network (WLAN) communication module, near-field communication (NFC) communication module, Zigbee communication module, and the like.

The wired communication module may include various wired communication modules such as a local area network (LAN) module, wide area network (WAN) module, value added network (VAN) module, or the like, and also include various cable communication modules such as a universal serial bus (USB), High Definition Multimedia Interface (HDMI), digital visual interface (DVI), recommended standard 232 (RS-232), power line communication, plain old telephone service (POTS), or the like.

The wired communication module may further include a Local Interconnect Network (LIN).

The wireless communication module may include wireless communication modules that support a variety of wireless communication methods such as a Global System for Mobile communication (GSM), Code Division Multiple Access (CDMA), wideband CDMA (WCDMA), Universal Mobile Telecommunications System (UMTS), Time Division Multiple Access (TDMA), Long Term Evolution (LTE), ultra wideband (UWB), and the like, in addition to a Wifi module and a Wibro module.

The first processor 112 may receive, from the server 2, information related to a voltage difference value between the first and second batteries corresponding to an output difference value between the LDC 102 and the BEQ 103. Here, the voltage difference value between the first and second batteries is a value inferred through learning in the server 2.

The first processor 112 may store the information related to the voltage difference value between the first and second batteries corresponding to the output difference value between the LDC 102 and the BEQ 103.

The first processor 112 may learn a pattern or a representative value of the output difference value to obtain charge times of the first and second batteries.

Hereinafter, a configuration of the first processor 112 learning a representative value of the output difference value is described.

The first processor 112 may receive an output value of the LDC 102 and an output value of the BEQ 103.

The first processor 112 may receive an output current value as the output value of the LDC 102. In the instant case, the first processor 112 may obtain a power value of the LDC 102 based on the received output current value and an output voltage value of the LDC 102. Here, the output voltage value of the LDC 102 may be preset and be approximately 24V.

The first processor 112 may receive an output voltage value as the output value of the LDC 102. In the instant case, the first processor 112 may obtain a power value based on the output voltage value and an output current value of the LDC 102.

The first processor 112 may receive an output value of the BEQ 103 through the first communicator 111.

The first processor 112 may receive an output current value as the output value of the BEQ 103. In the instant case, the first processor 112 may obtain a power value of the BEQ 103 based on the received output current value and an output voltage value of the BEQ 103. Here, the output voltage value of the BEQ 103 may be preset and be approximately 12V.

The first processor 112 may receive an output voltage value as the output value of the BEQ 103. In the instant case, the first processor 112 may obtain a power value of the BEQ 103 based on the received output current value and an output voltage value of the BEQ 103.

The first processor 112 may receive the power value from the LDC 102, and also receive the power value of the BEQ 103.

The first processor 112 may compare the output value of the LDC 102 and the output value of the BEQ 103, obtaining the output difference value between the output value of the LDC 102 and the output value of the BEQ 103. Here, the output difference value may be a power difference value. The first processor 112 may receive the output difference value in chronological order.

The first processor 112 may divide the plurality of output difference values into sections based on a reference power unit, and generate a histogram of the plurality of output difference values for each of the divided sections. Here, the reference power unit may be a preset power unit, and be approximately 0.1 kw.

The first processor 112 may be configured to determine whether a distribution of the histogram has normality based on the generated histogram of the time-series data.

Normality may be obtained by a normal distribution.

When it is determined that the distribution of the histogram has normality, the first processor 112 sets an average value of the plurality of output difference values as a representative value (that is an output representative value), and when it is not determined that the distribution of the histogram has normality, the first processor 112 sets a median value of the plurality of output difference value as a representative value.

The first processor 112 is configured to determine whether an accuracy of the set representative value and the obtained output difference value satisfies a performance, and when it is determined that the accuracy of the set representative value and the obtained output difference value satisfies a performance, learning the representative value end portions.

Here, the obtained output difference value is a value obtained by comparing the received output value of the LDC 102 and the received output value of the BEQ 103.

When it is determined that the accuracy is greater than or equal to a preset first reference accuracy, the first processor 112 is configured to determine that the performance is satisfied, and when it is determined that the accuracy is less than the preset first reference accuracy, the first processor 112 does not determine that the performance is satisfied and perform learning again.

The first processor 112 may repeat learning the representative value until the accuracy satisfies performance.

Hereinafter, a configuration of the first processor learning a pattern of the plurality of output difference values is described.

The first processor 112 may obtain the plurality of output difference values between the LDC 102 and the BEQ 103 in chronological order.

The first processor 112 generates windows using the output difference value received in chronological order.

When generating the window, the first processor 112 sets a window size and a stride, and generates a plurality of windows based on the set window size and stride. For example, the window size may be 1 and the stride may be 1.

The first processor 112 generates a label for each of the windows for the plurality of output difference values to generate a model for learning. In the present instance, a number may be assigned to the label in chronological order.

The first processor 112 generates a dataset of the generated windows of the time-series data. Here, the dataset may include a train set used when learning is performed, a validation set for validating and selecting a model, and a test set for testing a performance of the learned model.

The train set may be used for fitting a model, and the validation set may be used for checking an error in the model to select the model. The test set may be used to evaluate a generalization error.

The first processor 112 is configured to perform deep learning using the dataset.

The first processor 112 may use recurrent neural network (RNN) or convolutional recurrent neural network (CRNN) series as a deep learning model for learning a pattern of the time-series data.

The first processor 112 generates a model using the train set, is configured to perform learning using the generated model, validates learning of the model using the validation set, selects at least one model as a result of the validation, and tests a performance of the selected model using the test set.

The first processor 112 selects parameters that maximize a performance of the validation set after deep learning, and evaluates a performance of the selected parameters through the test set.

Here, the parameters may be the time-series data.

The first processor 112 may repeat the pattern learning until performance satisfaction.

An index for evaluating the performance may include at least one of an accuracy, precision, recall or F1 score.

Here, the accuracy is an index for determining how identical actual data (obtained output difference value) and selected data (selected parameters) are.

Accuracy=(the number of identical data)/(the number of total data)

The F1 score is an index that combines precision and recall, and includes a relatively high value when precision and recall are not biased to either side thereof. That is, the F1 score is a harmonic mean of precision and recall (sensitivity; true positive rate (TPR)), and as the precision is more similar to the recall, the F1 score increases. The F1 score includes a value of 0 to 1, and the higher F1 score, the higher the performance.

When it is determined that the accuracy is greater than or equal to a preset second reference accuracy and the F1 score is greater than or equal to a reference score, the first processor 112 is configured to determine that the performance is satisfied, and when it is determined that the accuracy is less than the preset second reference accuracy or the F1 score is less than the reference score, is configured to determine that the performance is not satisfied and is configured to perform learning again.

The first processor 112 obtains the output difference value through the representative value learning or the pattern learning, and infers a voltage difference value between the first and second batteries corresponding to the obtained output difference value based on information stored in the first memory.

When the inferred voltage difference value between the first and second batteries exceeds a reference value, the first processor 112 may be configured to determine a charge time so that charging of the first and second batteries start.

The first processor 112 is configured to determine whether the inferred voltage difference value exceeds the reference value, each time the number of driving cycles reach a preset number (N driving cycles). When it is determined that the inferred voltage difference value exceeds the reference value, the first processor 112 confirms a rate where the inferred voltage difference value exceeds the reference value. When it is determined that the confirmed rate is greater than or equal to a reference rate (P %), the first processor 112 is configured to perform charging of the first and second batteries.

Here, hyper parameters tuning may be performed on the preset number (N driving cycles), the reference rate, and the reference value.

A learning-related function may be operated through the first processor 112 and the first memory 113.

The first processor 112 may include a single or a plurality of processors.

In the present instance, the single or the plurality of processors may be a processor such as a central processing unit (CPU), an application processor (AP), a digital signal processor (DSP), and the like, or a learning-dedicated processor.

The single or the plurality of processors control input data to be processed according to predetermined operating rules or learning models stored in the first memory 113.

Alternatively, when the single or the plurality of processors are the learning-dedicated processor, the learning-dedicated processor may be designed with a software structure specialized for processing a specific learning model.

The learning model may include a deep neural network (DNN), for example, a convolutional neural network (CNN), a recurrent neural network (RNN), a restricted Boltzmann machine (RBM), deep belief network (DBN), bidirectional recurrent deep neural network (BRDNN), deep Q-Networks, or the like, without being limited thereto.

Such learning may be performed in a device itself where the learning according to an exemplary embodiment of the present disclosure is performed, or be performed through a separate server and/or system. For example, a learning algorithm may include a supervised learning, unsupervised learning, semi-supervised learning, or reinforcement learning, without being limited thereto.

The first processor 112 may be implemented as a memory that stores an algorithm for controlling operations of constituent components of the charging controller 110 or data about a program that reproduces the algorithm, and a processor that is configured to perform the above-described operations using the data stored in the memory. In the present instance, the memory and the processor may be provided as one chip, or provided as separate chips.

The first processor 112 may be an electronic control device provided in a vehicle 1. In the instant case, the first processor 112 may be implemented as a memory that stores an algorithm for controlling operations of constituent components of the vehicle 1 or data about a program that reproduces the algorithm, and a processor that is configured to perform the above-described operations using the data stored in the memory. In the present instance, the memory and the processor may be provided as one chip, or provided as separate chips.

The first memory 113 may store the voltage difference value corresponding to the output difference value transmitted from the server 2.

The first memory 113 may store the first reference accuracy, and information related to the reference value, the reference rate, a preset number of times for determining a charge time of the first and second batteries.

The first memory 113 may be implemented with at least one of a volatile memory such as a random access memory (RAM), a non-volatile memory such as a cache, a flash memory, a read only memory (ROM), a programmable read only memory (PROM), an erasable programmable read only memory (EPROM), an electrically erasable programmable read only memory (EEPROM), etc., or a recording media such as a Hard Disk Drive (HDD), or a compact disc read only memory (CD-ROM), without being limited thereto.

Meanwhile, each of the constituent components shown in FIG. 1 refers to a software component and/or a hardware component such as field-programmable gate array (FPGA) and application specific integrated circuit (ASIC).

At least one constituent component may be added or omitted corresponding to the performance of the constituent components of the charging controller and the vehicle illustrated in FIG. 1. Also, it will be easily understood by those skilled in the art that mutual positions of the constituent components may be modified corresponding to the performance or structure of the system.

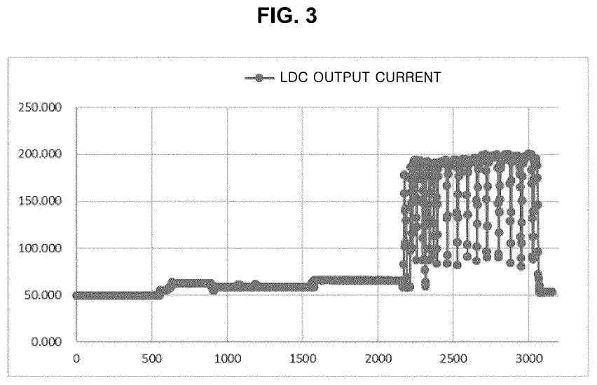

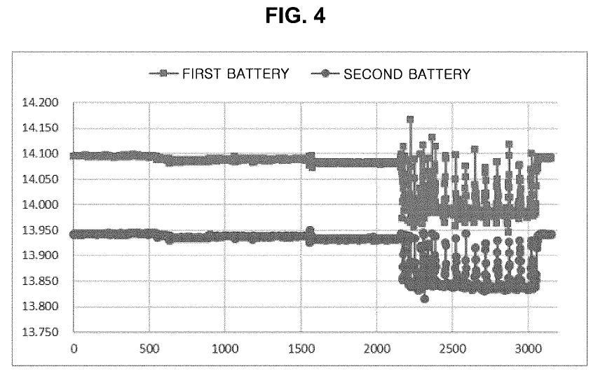

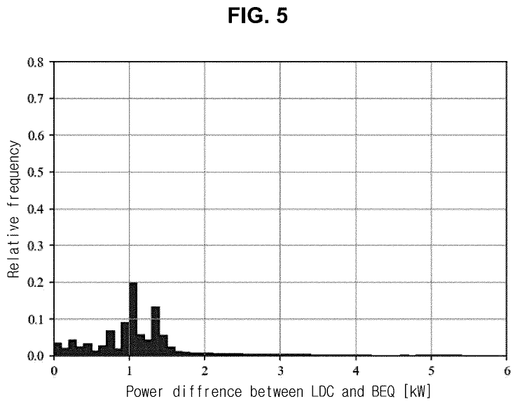

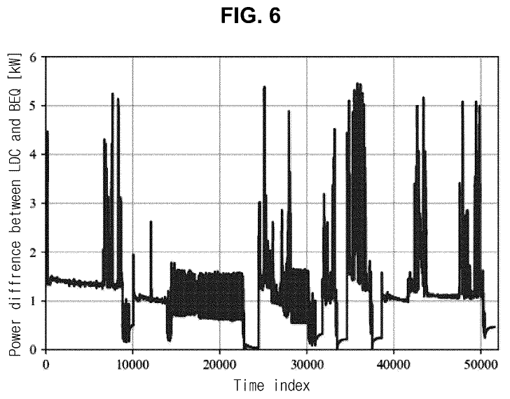

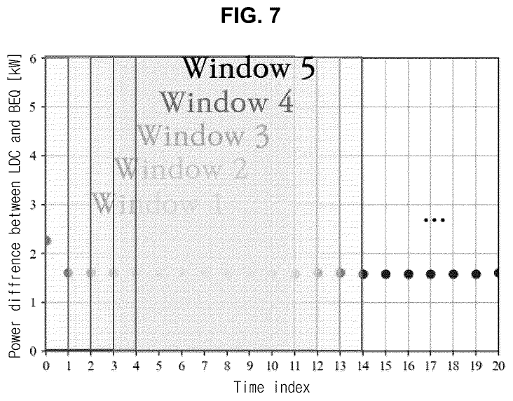

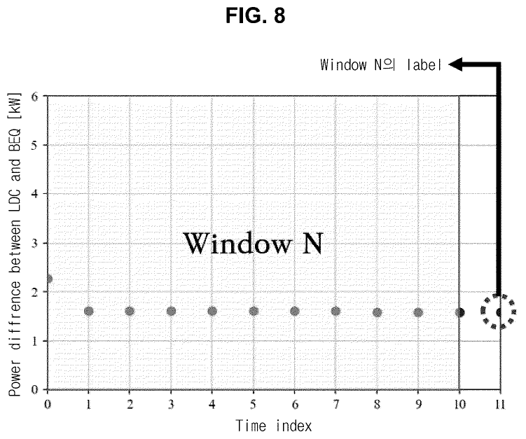

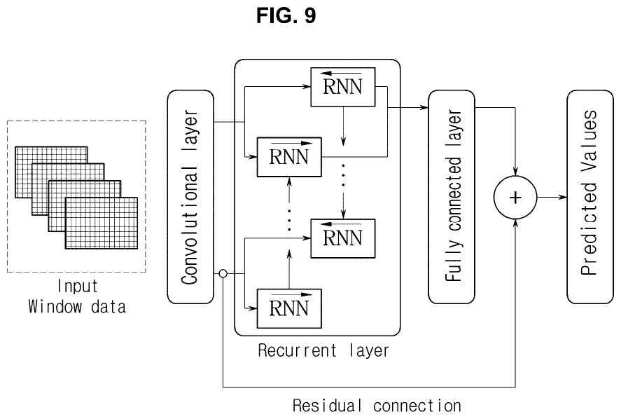

FIG. 2 illustrates a configuration of a server according to an exemplary embodiment of the present disclosure, which is described with reference to FIG. 3, FIG. 4, FIG. 5, FIG. 6, FIG. 7, FIG. 8, and FIG. 9.

FIG. 3 is a graph of an output current of a LDC received in a server according to an exemplary embodiment of the present disclosure. FIG. 4 is a graph of voltages of a first battery and a second battery detected by a first voltage sensor and a second voltage sensor, respectively, both of which perform communication with a server according to an exemplary embodiment of the present disclosure. FIG. 5 illustrates an example of a histogram generated in a server according to an exemplary embodiment of the present disclosure. FIG. 6 illustrates an example of time-series data of the plurality of output difference values of a server according to an exemplary embodiment of the present disclosure. FIG. 7 and FIG. 8 illustrate examples of windows generated in a server according to an exemplary embodiment of the present disclosure. FIG. 9 is a diagram illustrating an example of a learning model of a server according to an exemplary embodiment of the present disclosure.

The server 2 may perform communication with a plurality of vehicles 1, and transmit a predetermined reference value for charging the first battery 104 and the second battery 105 to the plurality of vehicles 1.

The server 2 may be a server of a vehicle manufacturer, or a server provided in a service center, a repair shop, and the like, for managing the vehicle 1. Also, the server 2 may be an application (i.e., app) server, a telematics server, or a platform server providing a service related to the vehicle 1. The server 2 may also be a server used in a vehicle development stage.

The server 2 may include a second communicator 210, a second processor 220 and a second memory 230.

The second communicator 210 may communicate with the LDC 102, the BEQ 103, a first voltage sensor 107, and a second voltage sensor 108.

The second communicator 210 may include at least one constituent component enabling communication with the vehicle 1 and communication among the constituent components of the server 2. For example, the second communicator 210 may include at least one of a short-range communication module, wireless communication module, or a wired communication module.

The short-range communication module may include a variety of short-range communication modules that transmit and receive signals in a short distance using a wireless communication network, such as a Bluetooth module, infrared communication module, radio frequency identification (RFID) communication module, wireless local access network (WLAN) communication module, near-field communication (NFC) communication module, Zigbee communication module, and the like.

The wired communication module may include various wired communication modules such as a local area network (LAN) module, wide area network (WAN) module, value added network (VAN) module, or the like, and also include various cable communication modules such as a universal serial bus (USB), high definition multimedia interface (HDMI), digital visual interface (DVI), recommended standard 232 (RS-232), power line communication, plain old telephone service (POTS), or the like.

The wired communication module may further include a Local Interconnect Network (LIN).

The wireless communication module may include wireless communication modules that support a variety of wireless communication methods such as a Global System for Mobile communication (GSM), Code Division Multiple Access (CDMA), wideband CDMA (WCDMA), Universal Mobile Telecommunications System (UMTS), Time Division Multiple Access (TDMA), Long Term Evolution (LTE), ultra wideband (UWB), and the like, in addition to a Wifi module and a Wibro module.

The LDC 102 and the BEQ 103 may be an LDC and a BEQ to be applied to the vehicle 1 which is mass-produced.

The LDC 102 and the BEQ 103 may be a same as the LDC 102 and the BEQ 103 illustrated in FIG. 1.

The LDC 102 may transmit an output value of the LDC 102 to the server 2.

The LDC 102 may include a first detector for detecting an output of the LDC 102, and perform communication.

The LDC 102 may transmit the output value detected by the first detector configured to the server as a first output value.

For example, the first detector may be a first power sensor configured for detecting power of the LDC 102.

As an exemplary embodiment of the present disclosure, the first detector may include a current sensor configured for detecting an output current of the LDC 102, and further include a voltage sensor configured for detecting an output voltage of the LDC 102.

The BEQ 103 may transmit an output value of the BEQ 103 to the server 2.

The BEQ 103 may include a second detector for detecting an output of the BEQ 103, and perform communication.

The BEQ 103 may transmit the output value detected by the second detector configured to the server as a second output value.

For example, the second detector may be a second power sensor configured for detecting power of the BEQ 103.

As an exemplary embodiment of the present disclosure, the second detector may include a current sensor configured for detecting an output current of the BEQ 103, and further include a voltage sensor configured for detecting an output voltage of the BEQ 103.

The first voltage sensor 107 may detect voltage values of both end portions of the first battery 104, and transmit the detected voltage values to the server 2 as a first voltage value.

The second voltage sensor 108 may detect voltage values of both end portions of the second battery 105, and transmit the detected voltage values to the server 2 as a second voltage value.

The first voltage sensor 107 and the second voltage sensor 108 may be communicable.

To obtain a charge time of the first battery 104 and the second battery 105, the first voltage sensor 107 and the second voltage sensor 108 are connected to the first battery 104 and the second battery 105, respectively, in a development stage of vehicle or charging controller. The first voltage sensor 107 and the second voltage sensor 108 are not included in a mass-produced vehicle.

The first voltage sensor 107 and the second voltage sensor 108 may be a sensor separable from the first battery 104 and the second battery 105.

That is, when the first output value is received from the LDC 102, the second communicator 210 transmits the received first output value to the second processor 220, and when the second output value is received from the BEQ 103, transmits the received second output value to the second processor 220.

When the first voltage value is received from the first voltage sensor 107, the second communicator 210 transmits the received first voltage value to the second processor 220, and when the second voltage value is received from the second voltage sensor 108, transmits the second voltage value to the second processor 220.

The second processor 220 may receive a voltage value of the first battery detected by the first voltage sensor, a voltage value of the second battery detected by the second voltage sensor, an output value of the LDC, and an output value of the BEQ for a predetermined time period. Here, the predetermined time period may be a time period required for learning.

The second processor 220 may perform at least one learning among a learning for obtaining a representative value of a plurality of output difference values obtained for the predetermined time period and a representative value of voltage difference values obtained for the predetermined time period, or a learning for obtaining a pattern of the plurality of output difference values of the LDC 102 and the BEQ 103 obtained for the predetermined time period and a pattern of voltage difference values obtained for the predetermined time period, and thus the second processor 220 may obtain a voltage difference value corresponding to the output difference values as inference information.

Hereinafter, a configuration of the second processor for representative value learning is described.

The second processor 220 may receive an output value of the LDC 102 through the second communicator 210.

As shown in FIG. 3, the second processor 220 may receive an output current value as the output value of the LDC 102. In the instant case, the second processor 220 may obtain a power value of the LDC 102 based on the received output current value and an output voltage value of the LDC 102. Here, the output voltage value of the LDC 102 may be preset and be approximately 24V.

The second processor 220 may receive an output voltage value as the output value of the LDC 102. In the instant case, the second processor 220 may obtain a power value based on the output voltage value and an output current value of the LDC 102.

The second processor 220 may receive an output value of the BEQ 103 through the second communicator 210.

The second processor 220 may receive an output current value as the output value of the BEQ 103. In the instant case, the second processor 220 may obtain a power value of the BEQ 103 based on the received output current value and an output voltage value of the BEQ 103. Here, the output voltage value of the BEQ 103 may be preset and be approximately 12V.

The second processor 220 may receive an output voltage value as the output value of the BEQ 103. In the instant case, the second processor 220 may obtain a power value of the BEQ 103 based on the received output voltage value and an output current value of the BEQ 103.

The second processor 220 may receive the power value from the LDC 102, and also receive the power value of the BEQ 103.

As shown in FIG. 4, the second processor 220 may receive a voltage value of the first battery 104 detected by the first voltage sensor 107 and a voltage value of the second battery 105 detected by the second voltage sensor 108, through the second communicator 210.

The second processor 220 may compare the output value of the LDC 102 and the output value of the BEQ 103, obtaining output difference value between the output value of the LDC 102 and the output value of the BEQ 103. Here, the output difference value may be a power difference value. The plurality of output difference values may be obtained in chronological order.

The second processor 220 may compare a voltage value of the first battery and a voltage value of the second battery, obtaining a voltage difference value between the voltage value of the first battery and the voltage value of the second battery. Here, the voltage difference value may be obtained in chronological order.

The second processor 220 may identify the voltage difference value corresponding to the output difference value by time, match and store the output difference value and the voltage difference value by time.

As shown in FIG. 5, the second processor 220 may divide the plurality of output difference values into sections based on a reference power unit, and generate a histogram of the plurality of output difference values for each of the divided sections. Here, the reference power unit may be a preset power unit, and be approximately 0.1 kw.

The second processor 220 may also confirm a voltage difference value corresponding to the plurality of output difference values for each section, and generate a histogram of the voltage difference values of battery for each section based on the confirmed voltage difference value for each section.

The second processor 220 may obtain a frequency where the plurality of output difference values occurs through statistical analysis of the generated histogram.

The second processor 220 may be configured to determine whether a distribution of the histogram has normality based on the generated histogram of the generated time-series data.

Normality may be obtained by a normal distribution.

The second processor 220 may be configured to determine whether a distribution of the histogram has normality based on the generated histogram of the generated voltage difference value.

When it is determined that the distribution of the histogram has normality, the second processor 220 sets an average value of a plurality of output difference values as a representative value, and when it is not determined that the distribution of the histogram has normality, the second processor 220 sets a median value of the plurality of output difference values as a representative value.

The second processor 220 is configured to determine whether an accuracy of the set representative value and the obtained output difference value satisfies a performance. Here, the obtained output difference value is a value obtained by comparing an output of the LDC and an output of the BEQ.

An index for evaluating the performance may include at least one of an accuracy, precision, recall or F1 score.

Here, the accuracy is an index for determining how identical actual data (a voltage difference value between voltage values detected by the two voltage sensors) and prediction data (set representative values) are.

Accuracy=(the number of identical data)/(the number of total data)

When it is determined that the accuracy is greater than or equal to a preset first reference accuracy, the second processor 220 is configured to determine that the performance is satisfied, and when the controller concludes that the accuracy is less than the preset first reference accuracy, is configured to determine that the performance is not satisfied and is configured to perform learning again.

The second processor 220 may repeat the representative value learning until performance satisfaction.

When it is determined that the accuracy satisfies the performance, the second processor 220 completes the voltage difference inference learning of the first and second batteries.

When it is determined that the performance is satisfied, the second processor 220 confirms a voltage difference value of the first and second batteries corresponding to the representative value of the time-series data, and store the confirmed voltage difference value of the first and second batteries as an inferred voltage difference value.

When it is determined that a distribution of histogram of voltage difference values has normality, the second processor 220 sets an average value of the voltage difference values as a representative value, and when it is not determined that the distribution of the histogram has normality, the second processor 220 sets a median value of the voltage difference values as a representative value of the voltage difference values.

The second processor 220 is configured to determine whether an accuracy of the set voltage difference value and the obtained voltage difference value satisfies a performance, and when it is not determined that the accuracy satisfies the performance, is configured to perform learning again. When it is determined that the accuracy satisfies the performance, the second processor 220 may match and store the representative value of the set voltage difference value and a representative value of the set time-series data, and transmit, to the vehicle, the matched representative values of the plurality of output difference values and the voltage difference value as inference information.

The second processor 220 may divide the plurality of output difference values obtained for a predetermined time period into a plurality of sections based on a reference power unit, perform learning to obtain a representative value of the voltage difference values for each of the divided sections, and obtain the representative value of the voltage difference values for each of the sections, obtained as a result of learning, as the inference information.

Hereinafter, a configuration of the second processor for pattern learning is described.

As shown in FIG. 6, the second processor 220 may receive time-series data of the plurality of output difference values between the LDC 102 and the BEQ 103 in chronological order.

The second processor 220 may obtain a voltage difference value between a voltage value of a first battery detected by the first voltage sensor and a voltage value of a second battery detected by the second voltage sensor in chronological order.

As shown in FIGS. 7 and 8, the second processor 220 generates windows using the plurality of output difference values received in chronological order.

When generating the window, the second processor 220 sets a window size and a stride, and generates a plurality of windows based on the set window size and stride. For example, the window size may be 1 and the stride may be 1.

As shown in FIG. 8, the second processor 220 generates a label for each of the windows for the plurality of output difference values to generate a prediction model. In the present instance, a number may be assigned to the label in chronological order.

The second processor 220 may be configured to generate windows of voltage difference values corresponding to the time-series data.

The second processor 220 generates a dataset of the generated windows of the time-series data. Here, the dataset may include a train set used when learning is performed, a validation set for validating and selecting a model, and a test set for testing a performance of the learned model.

The train set may be used for fitting a model, and the validation set may be used for checking an error in the model to select the model. The test set may be used to evaluate a generalization error.

The second processor 220 is configured to perform deep learning using the dataset.

As shown in FIG. 9, the second processor 220 may use convolutional recurrent neural network (CRNN) series as a deep learning model for learning a pattern of the time-series data.

A model of CRNN series includes a general configuration, which is not described in detail.

The second processor 220 may also use recurrent neural network (RNN) series as a deep learning model for learning a pattern of the time-series data.

The second processor 220 generates a model using the train set, is configured to perform learning using the generated model, validates learning of the model using the validation set, selects at least one model as a result of the validation, and tests a performance of the selected model using the test set.

The second processor 220 selects parameters that maximize a performance of the validation set after deep learning, and evaluates a performance of the selected parameters through the test set.

The second processor 220 may repeat the pattern learning until performance satisfaction.

An index for evaluating the performance may include at least one of an accuracy, precision, recall or F1 score.

Here, the accuracy is an index for determining how identical actual data (obtained time-series data) and selected data (selected parameters) are.

Accuracy=(the number of identical data)/(the number of total data)

The F1 score is an index that combines precision and recall, and includes a relatively high value when precision and recall are not biased to either side thereof. That is, the F1 score is a harmonic mean of precision and recall (sensitivity; true positive rate (TPR)), and as the precision is more similar to the recall, the F1 score increases. The F1 score includes a value of 0 to 1, and the higher F1 score, the higher the performance.

When it is determined that the accuracy is greater than or equal to a preset second reference accuracy and the F1 score is greater than or equal to a reference score, the second processor 220 is configured to determine that the performance is satisfied, and when it is determined that the accuracy is less than the preset second reference accuracy or the F1 score is less than the reference score, is configured to determine that the performance is not satisfied and is configured to perform learning again.

When it is determined as performance satisfaction, the second processor 220 confirms voltage difference value of the first and second batteries corresponding to the selected parameter, and store the confirmed voltage difference value of the first and second batteries as an inferred voltage difference value.

To generate a prediction model, the second processor 220 generates a plurality of windows for the obtained voltage difference value, and generates a label for each of the windows. In the present instance, a number may be assigned to the label in chronological order.

When generating the windows for the voltage difference value, the second processor 220 sets a window size and a stride, and generates a plurality of windows based on the set window size and stride. For example, the window size may be 1 and the stride may be 1.

The second processor 220 generates a dataset of the generated windows of the voltage difference value. Here, the dataset may include a train set used when learning is performed, a validation set for validating and selecting a model, and a test set for testing a performance of the learned model.

The second processor 220 is configured to perform deep learning using the dataset.

The second processor 220 may use CRNN or RNN series as a deep learning model for learning a pattern of the voltage difference value.

The second processor 220 generates a model using the train set, is configured to perform learning using the generated model, validates learning of the model using the validation set, selects parameters that maximize a performance of the validation set, and evaluates a performance of the selected parameters using the test set.

When it is determined that the accuracy is greater than or equal to a preset third reference accuracy and the F1 score is greater than or equal to a reference score, the second processor 220 is configured to determine that the performance is satisfied, and when it is determined that the accuracy is less than the preset third reference accuracy or the F1 score is less than the reference score, is configured to determine that the performance is not satisfied and is configured to perform learning again.

When it is determined that the performance is satisfied, the second processor 220 may match and store the selected parameter value (voltage difference value) and the selected parameter value (time-series data), and transmit, to the vehicle, the matched voltage difference value and output difference value as inference information.

The second processor 220 may infer a voltage difference value of batteries through any one of representative value learning or pattern learning.

The second processor 220 may transmit the inferred voltage difference value of the first and second batteries, to the vehicle and to the charging controller 110.

A learning-related function is operated through the second processor 220 and the second memory 230.

The second processor 220 may include a single or a plurality of processors.

In the present instance, the single or the plurality of processors may be a processor such as a central processing unit (CPU), an application processor (AP), a digital signal processor (DSP), and the like, or a learning-dedicated processor.

The single or the plurality of processors control input data to be processed according to predetermined operating rules or learning models stored in the second memory 230.

Alternatively, when the single or the plurality of processors are the learning-dedicated processor, the learning-dedicated processor may be designed with a software structure specialized for processing a predetermined learning model.

The learning model may include a deep neural network (DNN), for example, a convolutional neural network (CNN), a recurrent neural network (RNN), a restricted Boltzmann machine (RBM), deep belief network (DBN), bidirectional recurrent deep neural network (BRDNN), deep Q-Networks, or the like, without being limited thereto.

Such learning may be performed in a device itself where the learning according to an exemplary embodiment of the present disclosure is performed, or through a separate server and/or system. For example, a learning algorithm may include a supervised learning, unsupervised learning, semi-supervised learning, or reinforcement learning, without being limited thereto.

The second processor 220 may be implemented as a memory that stores an algorithm for controlling operations of constituent components of the server 2 or data about a program that reproduces the algorithm, and a processor that is configured to perform the above-described operations using the data stored in the memory. In the present instance, the memory and the processor may be provided as one chip, or provided as separate chips.

The second memory 230 may store the first reference accuracy, the second reference accuracy, and the reference score.

The second memory 230 may be implemented with at least one of a volatile memory such as a random access memory (RAM), a non-volatile memory such as a cache, a flash memory, a read only memory (ROM), a programmable read only memory (PROM), an erasable programmable read only memory (EPROM), an electrically erasable programmable read only memory (EEPROM), etc., or a recording media such as a Hard Disk Drive (HDD), or a compact disc read only memory (CD-ROM), without being limited thereto.

Meanwhile, each of the constituent components shown in FIG. 2 refers to a software component and/or a hardware component such as field-programmable gate array (FPGA) and application specific integrated circuit (ASIC).

At least one constituent component may be added or omitted corresponding to the performance of the constituent components of the server 2 illustrated in FIG. 2. Also, it will be easily understood by those skilled in the art that mutual positions of the constituent components may be modified corresponding to the performance or structure of the system.

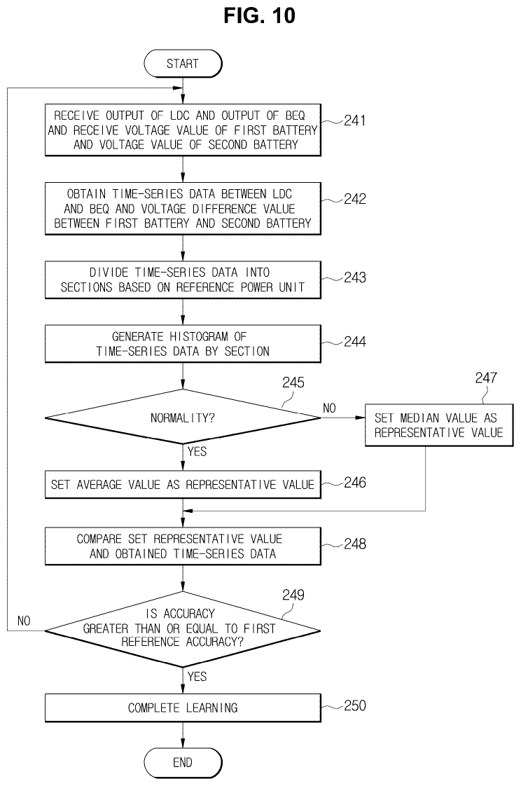

FIG. 10 is a flowchart illustrating operations of representative value learning in learning of a server according to an exemplary embodiment of the present disclosure.

The server may receive an output value of the LDC 102 and an output value of the BEQ 103 through the second communicator 210 (241).

The server may receive a voltage value of the first battery 104 detected by the first voltage sensor 107, and a voltage value of the second battery 105 detected by the second voltage sensor 108 through the second communicator 210 (241).

The server may compare the output value of the LDC 102 and the output value of the BEQ 103, obtaining output difference value between the output value of the LDC 102 and the output value of the BEQ 103. Here, the output difference value may be a power difference value. The output difference value may be obtained in chronological order.

The server may compare the voltage value of the first battery and the voltage value of the second battery, obtaining a voltage difference value between the voltage value of the first battery and the voltage value of the second battery (242). The voltage difference value may be obtained in chronological order.

The server may identify the voltage difference value corresponding to the output difference value by time, and match and store the voltage difference value and the output difference value by time.

The server divides the plurality of output difference values into sections based on a reference power unit (243), and generates a histogram of the plurality of output difference values for each of the divided sections (244). Here, the reference power unit may be a preset power unit, and be approximately 0.1 kw.

The server may also confirm the voltage difference value corresponding to the output difference value for each section, and generate a histogram of the voltage difference values of battery for each section based on the confirmed voltage difference value for each section.

The server may be configured to determine whether a distribution of the histogram has normality based on the generated histogram of the output difference value (245).

Normality may be obtained by a normal distribution.

When it is determined that the distribution of the histogram has normality, the server is configured to set an average value of a plurality of output difference values as a representative value (246), and when it is not determined that the distribution of the histogram has normality, the server is configured to set a median value of the plurality of output difference values as a representative value (247).

The server is configured to determine whether an accuracy of the set representative value and the obtained output difference value satisfies a performance, by comparing (248) the set representative value and the obtained time-series data. Here, the obtained output difference value is a value obtained by comparing an output of the LDC and an output of the BEQ.

When it is determined that the accuracy is greater than or equal to a preset first reference accuracy (249), the server is configured to determine that the performance is satisfied, and when it is determined that the accuracy is less than the preset first reference accuracy, is configured to determine that the performance is not satisfied and is configured to perform learning again.

The server may repeat the representative value learning until performance satisfaction.

When it is determined as performance satisfaction, the server may confirm a voltage difference value of the first and second batteries corresponding to the representative value, and store the confirmed voltage difference value of the first and second batteries as an inferred voltage difference value.

When it is determined that the accuracy satisfies the performance, the server completes a voltage difference inference learning of the first and second batteries (250).

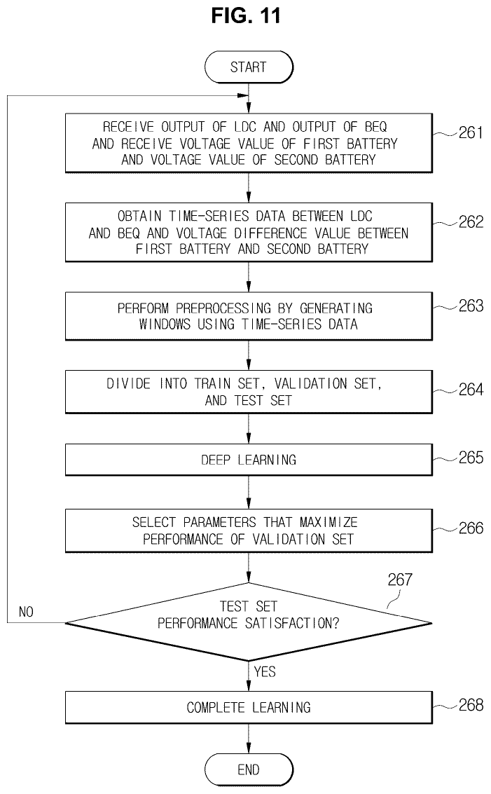

FIG. 11 is a flowchart illustrating operations of pattern learning in learning of a server according to an exemplary embodiment of the present disclosure.

The server may receive an output value of the LDC 102 and an output value of the BEQ 103 in chronological order, and receive a voltage value of the first battery detected by the first voltage sensor and a voltage value of the second battery detected by the second voltage sensor (261).

The server may obtain output difference value between the output value of the LDC 102 and the output value of the BEQ 103, and obtain a voltage difference value between the voltage value of the first battery detected by the first voltage sensor and the voltage value of the second battery detected by the second voltage sensor in chronological order (262).

The server may perform preprocessing for learning by generating windows using the output difference value received in chronological order (263).

The server may be configured to generate windows using the voltage difference value obtained in chronological order.

When generating the windows of the time-series data, the server is configured to set a window size and a stride, and generates a plurality of windows based on the set window size and stride. For example, the window size may be 1 and the stride may be 1.

The server generates a label for each of the windows for the output difference value to generate a prediction model. In the present instance, a number may be assigned to the label in chronological order.

The server may be configured to generate a label of each of the windows for the voltage difference value obtained in chronological order.

The server may be configured to generate windows of the voltage difference value corresponding to the time-series data.

The server generates a dataset of the generated windows of the output difference value (264). Here, the dataset may include a train set used when learning is performed, a validation set for validating and selecting a model, and a test set for testing a performance of the learned model.

The train set may be used for fitting a model, and the validation set may be used for checking an error in the model to select the model. The test set may be used to evaluate a generalization error.

The server is configured to perform deep learning using the dataset (265).

The server generates a model using the train set, is configured to perform learning using the generated model, and validates learning of the model using the validation set.

The server is configured to select parameters that maximize a performance of the validation set (266), and evaluates a performance of the selected parameters through the test set.

The server is configured to determine whether an accuracy and a F1 score of the test set satisfy a performance (267).

An index for evaluating the performance may include at least one of an accuracy, precision, recall or F1 score.

Here, the accuracy is an index for determining how identical actual data (obtained time-series data) and selected data (selected parameters) are.

Accuracy=(the number of identical data)/(the number of total data)

The F1 score is an index that combines precision and recall, and includes a relatively high value when precision and recall are not biased to either side thereof. That is, the F1 score is a harmonic mean of precision and recall (sensitivity; true positive rate (TPR)), and as the precision is more similar to the recall, the F1 score increases. The F1 score includes a value of 0 to 1, and the higher F1 score, the higher the performance.

For example, when it is determined that the accuracy is greater than or equal to a preset second reference accuracy and the F1 score is greater than or equal to a reference score, the server is configured to determine that the performance is satisfied.

When it is determined as performance satisfaction, the server may confirm a voltage difference value of the first and second batteries corresponding to the selected parameter, and store the confirmed voltage difference value of the first and second batteries as an inferred voltage difference value (268).

When it is determined that the accuracy is less than the preset second reference accuracy or the F1 score is less than the reference score, the server is configured to determine that the performance is not satisfied and is configured to perform learning again.

The server may repeat pattern learning until performance satisfaction.

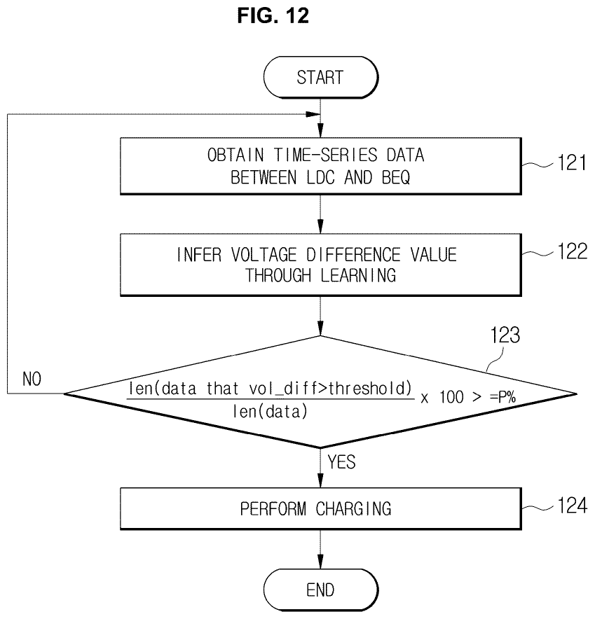

FIG. 12 is a flowchart illustrating a control of a vehicle according to an exemplary embodiment of the present disclosure.

A vehicle may confirm an output value of the LDC 102 and an output value of the BEQ 103.

The vehicle compares the output value of the LDC 102 and the output value of the BEQ 103, obtaining output difference value between the output value of the LDC 102 and the output value of the BEQ 103 (121). Here, the output difference value may be a power difference value. The output difference value may be obtained in chronological order.

The vehicle is configured to perform pattern learning or representative value learning for the time-series data.

The vehicle obtains the output difference value through learning, and infers a voltage difference value of the first and second batteries corresponding to the obtained output difference value based on information stored in the first memory (122).

The vehicle may obtain a charge time, when the inferred voltage difference value of the first and second batteries exceeds a reference value.

Each time the number of driving cycles reach a preset number (N driving cycles), the vehicle is configured to determine whether the inferred voltage difference value exceeds the reference value. When it is determined that the inferred voltage difference value exceeds the reference value, the vehicle confirms a rate where the inferred voltage difference value exceeds the reference value. When it is determined that the confirmed rate is greater than or equal to a reference rate P % (123), the vehicle is configured to determine as a charge time of the first and second batteries and is configured to perform charging of the first and second batteries (124).

As is apparent from the above, according to the exemplary embodiments of the present disclosure, a low voltage phenomenon and a voltage unbalancing phenomenon of first and second batteries of a vehicle, and a phenomenon in which a vehicle may not start may be improved.

According to the exemplary embodiments of the present disclosure, the first and second batteries may be charged at an optimized point in time, extending lifespans of the first and second batteries.

According to the exemplary embodiments of the present disclosure, a charge time of the first and second batteries may be determined through learning, determining a robust charge time compared to existing technologies.

According to the exemplary embodiments of the present disclosure, a marketability and competitiveness of a vehicle, user satisfaction, and user's reliability may be improved. A marketability and competitiveness of a commercial vehicle including two auxiliary batteries may be enhanced.

Meanwhile, the above-described embodiments may be stored in a form of a recording medium storing computer-executable instructions. The instructions may be stored in a form of a program code, and when executed by a processor, the instructions may perform operations of the disclosed exemplary embodiments of the present disclosure. The recording medium may be implemented as a computer-readable recording medium.

The computer-readable recording medium includes all kinds of recording media in which instructions which may be decoded by a computer are stored of, for example, a read only memory (ROM), random access memory (RAM), magnetic tapes, magnetic disks, flash memories, optical recording medium, and the like.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

In the present specification, unless stated otherwise, a singular expression includes a plural expression unless the context clearly indicates otherwise.

In exemplary embodiments of the present disclosure, “at least one of A and B” may refer to “at least one of A or B” or “at least one of combinations of one or more of A and B”. Furthermore, “one or more of A and B” may refer to “one or more of A or B” or “one or more of combinations of one or more of A and B”.

In the exemplary embodiment of the present disclosure, it should be understood that a term such as “include” or “have” is directed to designate that the features, numbers, steps, operations, elements, parts, or combinations thereof described in the specification are present, and does not preclude the possibility of addition or presence of one or more other features, numbers, steps, operations, elements, parts, or combinations thereof.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain predetermined principles of the present disclosure and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A server, comprising:
a communicator configured to perform communication with a first voltage sensor configured to detect a voltage value of a first battery, a second voltage sensor configured to detect a voltage value of a second battery, a low DC-DC converter, and a battery equalizer (BEQ) connected to the low DC-DC converter; and
a processor communicatively connected to the communicator and configured to:
obtain a voltage difference value between the voltage value of the first battery detected by the first voltage sensor and the voltage value of the second battery detected by the second voltage sensor,
obtain an output difference value between an output value of the low DC-DC converter and an output value of the BEQ, and
transmit, to a vehicle, a voltage difference value corresponding to the output difference value as inference information.

2. The server of claim 1, wherein the processor is further configured to:
obtain a plurality of voltage difference values corresponding to the output difference value for a predetermined time period,
divide the plurality of voltage difference values obtained for the predetermined time period into a plurality of sections,
perform learning to obtain a representative value of voltage difference values for each of the divided sections, and
obtain, as the inference information, the representative value of the voltage difference values for each of the sections obtained as a result of the learning.

3. The server of claim 2, wherein the processor is further configured to:
generate a histogram of the voltage difference values for each of the sections,
determine whether the generated histogram has normality,
when the processor concludes that the generated histogram has the normality, set an average value of the voltage difference values as the representative value, and
when the processor concludes that the generated histogram has no normality, set a median value of the voltage difference values as the representative value.

4. The server of claim 3, wherein, based on an accuracy between the set representative value and the obtained voltage difference value being greater than or equal to a first reference accuracy, the processor is further configured to conclude that a performance is satisfied and complete the learning.

5. The server of claim 1, wherein the processor is further configured to:
perform learning to obtain an output representative value of a plurality of output difference values obtained for a predetermined time period,
perform learning to obtain a voltage representative value of a plurality of voltage difference values obtained for the predetermined time period, and
obtain, as the inference information, the voltage representative value and the output representative value.

6. The server of claim 1, wherein the processor is further configured to:
learn a first pattern of a plurality of output difference values obtained for a predetermined time period and a second pattern of a plurality of voltage difference values obtained for the predetermined time period, and
obtain, the inference information, based on the learned first pattern and second pattern.

7. The server of claim 6, wherein the processor is further configured to:
generate windows of the plurality of output difference values obtained for the predetermined time period,
divide the generated windows into a train set, a validation set, and a test set,
generate a model using the train set,
validate the generated model using the validation set,
select output difference value that maximizes a performance of the validation set,
evaluate a performance of the selected output difference value using the test set, and
based on the performance being satisfied, complete the learning.

8. The server of claim 7, wherein the processor is further configured to:
determine an accuracy and a F1 score based on the selected output difference value and obtained time-series data, and
based on the determined accuracy being greater than or equal to a second reference accuracy and the determined F1 score being greater than or equal to a reference score, conclude that the performance is satisfied.

9. The server of claim 6, wherein the processor is further configured to:
generate windows of the voltage difference values obtained for the predetermined time period,
divide the generated windows into a train set, a validation set, and a test set,
generate a model using the train set,
validate the generated model using the validation set,
select a voltage difference value that maximizes a performance of the validation set,
evaluate a performance of the selected voltage difference value using the test set, and
based on the performance of the selected voltage difference value being satisfied, complete the learning.

10. The server of claim 9, wherein the processor is further configured to:
determine an accuracy and a F1 score based on the selected voltage difference value and the obtained voltage difference value, and
based on the determined accuracy being greater than or equal to a third reference accuracy and the determined F1 score being greater than or equal to a reference score, conclude that the performance of the selected output difference value is satisfied.

11. The server of claim 2, wherein the processor is further configured to use a recurrent neural network (RNN) model or a convolutional recurrent neural network (CRNN) model for the learning.

12. A vehicle, comprising:
a low-voltage DC-DC converter (LDC) configured to convert a voltage of a battery into a first voltage;
a first battery connected to the LDC;
a second battery connected to the first battery;
a BEQ connected to the LDC, the first battery, the second battery and a load, and configured to convert the first voltage applied to the BEQ into a second voltage, and maintain a voltage balance between the first battery and the second battery using the second voltage;
a memory configured to store inference information related to a voltage difference value corresponding to an output difference value received from a server; and
a processor configured to obtain an output difference value between an output value of the LDC and an output value of the BEQ, obtain a voltage difference value corresponding to the obtained output difference value based on the inference information stored in the memory, and determine a charge time of the first battery and the second battery based on the obtained voltage difference value and a reference value.

13. The vehicle of claim 12, wherein the processor is further configured to:
determine whether the obtained voltage difference value exceeds the reference value,
when the processor concludes that the obtained voltage difference value exceeds the reference value, identify a rate where the obtained voltage difference value exceeds the reference value, and
when the processor concludes that the identified rate is greater than or equal to a reference rate, determine as the charge time of the first battery and the second battery to perform charging of the first and second batteries.

14. The vehicle of claim 13, wherein the processor is further configured to, in response to a number of driving cycles reaching a preset number of times, determine whether it is the charge time of the first battery and the second battery to perform the charging of the first and second batteries.

15. The vehicle of claim 12, wherein the processor is further configured to, obtain a plurality of output difference values for a predetermined time period, and perform learning to obtain an output representative value of the plurality of output difference values.

16. The vehicle of claim 15, wherein the processor is further configured to:
divide the plurality of output difference values obtained for the predetermined time period into a plurality of sections,
generate a histogram of the plurality of output difference values for each of the divided sections,
determine whether the generated histogram has normality,
when the processor concludes that the generated histogram has the normality, set an average value of the plurality of output difference values as the output representative value, and
when the processor concludes that the generated histogram has no normality, set a median value of the plurality of output difference values as the output representative value.

17. The vehicle of claim 16, wherein, based on an accuracy between the set output representative value and the obtained output difference value being greater than or equal to a first reference accuracy, the processor is further configured to conclude that a performance is satisfied and complete the learning.

18. The vehicle of claim 17, wherein the processor is further configured to:
generate windows of the plurality of output difference values obtained for the predetermined time period,
divide the generated windows into a train set, a validation set, and a test set,
generate a model using the train set,
validate the generated model using the validation set,
select output difference value that maximizes a performance of the validation set,
evaluate a performance of the selected output difference value using the test set, and
based on the performance of the selected output difference value being satisfied, complete the learning.

19. The vehicle of claim 18, wherein the processor is further configured to:
determine an accuracy and a F1 score based on the selected output difference value and the obtained output difference value, and
based on the determined accuracy being greater than or equal to a third reference accuracy and the determined F1 score being greater than or equal to a reference score, conclude that the performance of the selected output difference value is satisfied.

20. The vehicle of claim 13, wherein the processor is further configured to use a RNN model or a CRNN model for the learning.
